(19) United States
(12) Patent Application Publication
(10) Pub. No.: US 2026/0184826 A1
(43) Pub. Date: Jul. 2, 2026

(54) MULTIFUNCTIONAL VINYLBENZYL COMPOUND, RESIN COMPOSITION, PREPREG, RESIN FILM, METAL-CLAD LAMINATE, PRINTED WIRING BOARD, AND SEMICONDUCTOR PACKAGE

(71) Applicant: RESONAC CORPORATION, Tokyo (JP)

(72) Inventors: Takeshi YAMASHITA, Tokyo (JP); Tomohiko KOTAKE, Tokyo (JP)

(21) Appl. No.: 18/860,599

(22) PCT Filed: Apr. 23, 2024
(86) PCT No.: PCT/JP2024/015876

§ 371 Date: Oct. 25, 2024

(30) Foreign Application Priority Data
Apr. 28, 2023 (JP) 2023-074727

(51) Int. Cl. C08F 12/34; C08F 299/02; C08J 5/18; C08J 5/24

(52) U.S. Cl. CPC C08F 12/34; C08F 299/02; C08J 5/18; C08J 5/24; C08J 2365/00

(57) ABSTRACT

A multifunctional vinylbenzyl compound is obtained by a reaction between a compound having an aromatic condensed ring, a compound having a biphenylene group, and a compound having a vinylbenzyl group. Further, a resin composition, a prepreg, a resin film, a metal-clad laminate, a printed wiring board, and a semiconductor package are obtained using the multifunctional vinylbenzyl compound.

### TECHNICAL FIELD

The present invention relates to a multifunctional vinylbenzyl compound, a resin composition, a prepreg, a resin film, a metal-clad laminate, a printed wiring board, and a semiconductor package.

### BACKGROUND ART

Metal-clad laminates typified by copper-clad laminates, prepregs that can be used in metal-clad laminates, and semiconductor packages that use metal-clad laminates are used in a wide variety of electronic devices, including mobile communication devices such as smart phones, as well as personal computers, industrial computers, servers, large-scale servers, routers and mobile base stations and the like. Further, they are also used in electronic equipment installed in household electric appliances and vehicles and the like. Among these uses, electronic communication devices are seeing increased demands for processing enormous amounts of data at high speed due to the growth of 5G.

In an electronic device, when a large amount of data must be processed at high speed, a substrate material that exhibits little transmission loss in the high frequency region is required. Resins with superior dielectric characteristics are used as these substrate materials, and although substrates with low transmission loss have been provided, developments in communication technology in recent years mean that the development of resins having even more superior dielectric characteristics is now required.

In recent years, due to the increased awareness of environmental issues, environmental considerations are now essential when developing electronic devices and electronic componentry. Accordingly, the demand is growing for halogen-free phosphorus-based flame retardants, which are used instead of conventional halogen-containing flame retardants as additives for substrate materials. However, when a large amount of a phosphorus-based flame retardant is included in order to enhance the flame retardancy, deterioration in the dielectric characteristics of the substrate material can be problematic.

Patent Document 1 proposes a resin composition having excellent heat resistance and flame retardancy for the cured product while maintaining the excellent dielectric characteristics of a polyphenylene ether, the resin composition comprising a modified polyphenylene ether compound, a crosslinking curing agent and a flame retardant, wherein the flame retardant contains a compatible phosphorus compound that is compatible with a mixture of the modified polyphenylene ether compound and the crosslinking curing agent, and an incompatible phosphorus compound that is incompatible with the mixture.

### CITATION LIST

### Patent Document

Patent Document 1: JP 2015-86330 A

### SUMMARY OF THE INVENTION

### Technical Problem

The technology disclosed in Patent Document 1 attempts to suppress inhibition of the curing reaction between the modified polyphenylene ether compound and the crosslinking curing agent and enhance the flame retardancy of the cured product by using a compatible phosphorus compound and an incompatible phosphorus compound as flame retardants. However, in the resin composition disclosed in Patent Document 1, the modified polyphenylene ether contains a polyphenylene ether chain in which a substituent having a carbon-carbon unsaturated double bond is bonded to the oxygen atom of the phenol group instead of the phenol group hydrogen atom. This type of modified polyphenylene ether contains a large number of ether linkages, and there is a possibility that the compound will be unable to satisfy recent demands for more stringent dielectric characteristics. Further, in the technology disclosed in Patent Document 1, no investigation was conducted as to the flame retardancy of the thermosetting resin itself.

The present invention has the objects of providing a multifunctional vinylbenzyl compound for providing products having superior flame retardancy and excellent dielectric characteristics, as well as a resin composition containing the multifunctional vinylbenzyl compound, and a prepreg, a resin film, a metal-clad laminate, a printed wiring board and a semiconductor package produced using this resin composition.

### Solution to Problem

The present invention includes the following embodiments. However, the present invention is not limited to the embodiments described below.

One embodiment relates to a multifunctional vinylbenzyl compound obtained by a reaction between a compound having an aromatic condensed ring, a compound having a biphenylene group, and a compound having a vinylbenzyl group.

Another embodiment relates to a multifunctional vinylbenzyl compound containing a unit having an aromatic condensed ring and a unit having a biphenylene group, wherein
the multifunctional vinylbenzyl compound has a structure in which the aromatic condensed rings are respectively bonded, either directly or via a linking group, to two carbon atoms on the rings of the biphenylene group, with the linking group being a divalent hydrocarbon group, and
also has a vinylbenzyl group bonded directly to a carbon atom on a ring of the aromatic condensed ring.

Yet another embodiment relates to a multifunctional vinylbenzyl compound represented by formula (1) shown below.

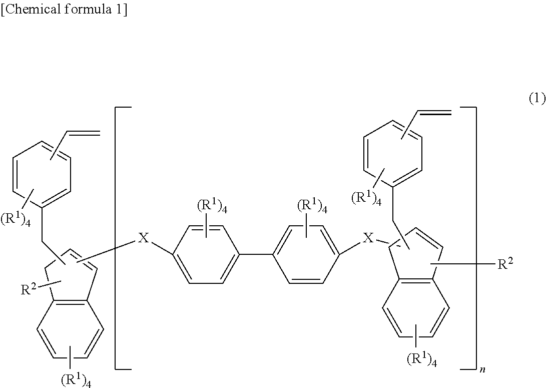

In formula (1):
each R¹ independently represents a monovalent group of 1 to 30 carbon atoms or a hydrogen atom,
each R² independently represents a monovalent group of 1 to 30 carbon atoms, a hydrogen atom, or a bonding location with another structure,
each X independently represents an alkylene group of 1 to 4 carbon atoms or a single bond, and
n is an integer of 1 or greater.

### Advantageous Effects of Invention

The present invention is able to provide a multifunctional vinylbenzyl compound for providing products having superior flame retardancy and excellent dielectric characteristics, as well as a resin composition containing the multifunctional vinylbenzyl compound, and a prepreg, a resin film, a metal-clad laminate, a printed wiring board and a semiconductor package produced using this resin composition.

### DETAILED DESCRIPTION OF THE EMBODIMENTS

Embodiments of the present invention are described below in detail. However, the present invention is not limited to the embodiments described below.

In this description, numerical ranges indicated using the expression “a to b” indicate a range that includes the numerical values before and after the “to” as the minimum value and maximum value respectively. In the case of numerical ranges listed in a stepwise manner in this description, the upper limit value or lower limit value from any particular numerical range may be arbitrarily combined with the upper limit value or lower limit value from another numerical range. In a numerical range disclosed in this description, the upper limit value or lower limit value from the numerical range may be used to replace a value shown in an example. In this description, unless specifically stated otherwise, each component may be composed of a single substance or two or more substances. In this description, the amount of each component in a resin composition, in the case where a plurality of substances corresponding with that component exist in the resin composition, unless specifically stated otherwise, means the total amount of the plurality of substances that exist in the resin composition.

In this description, unless specifically stated otherwise, polymer weight average molecular weight (Mw) and number average molecular weight (Mn) values represent measured values measured using the following measurement method.

The weight average molecular weight (Mw) and number average molecular weight (Mn) values were determined using gel permeation chromatography (GPC), from a calibration curve produced using standard polystyrenes. The calibration curve was approximated as a cubic equation using a set of standard polystyrenes: TSK Standard Polystyrenes (Types A-500, A-2500, A-5000, F-2, F-2, F-4, F-40, F-128 and F-288) (brand names) manufactured by Tosoh Corporation. The GPC measurement conditions are shown below.
Apparatus: high-speed GPC device HLC-8320GPC (product name, Tosoh Corporation)
Detector: ultraviolet absorption detector UV-8320 (product name, Tosoh Corporation)
Columns: guard column: TSKgel guard column Super (HZ)-M+, columns: TSKgel SuperMultipore HZ-M (two columns), reference columns: TSKgel SuperH-RC (two columns), (all product names from Tosoh Corporation)
Column sizes: 4.6×20 mm (guard column), 4.6×150 mm (columns), 6.0×150 mm (reference columns)
Eluent: tetrahydrofuran
Sample concentration: 10 mg/mL
Injection volume: 2 μL
Flow rate: 0.35 mL/minute
Measurement temperature: 40° C.

### [Multifunctional Vinylbenzyl Compound]

One embodiment of the invention provides a multifunctional vinylbenzyl compound obtained by a reaction between a compound having an aromatic condensed ring, a compound having a biphenylene group, and a compound having a vinylbenzyl group.

The multifunctional vinylbenzyl compound may contain a biphenyl skeleton derived from a compound having a biphenylene group. The biphenylene skeleton is a thermally and chemically stable skeleton, is resistant to degradation at high temperature, and can enhance the flame retardancy of the resin cured product obtained using the multifunctional vinylbenzyl compound.

Further, together with the aromatic condensed ring derived from the compound having an aromatic condensed ring and the vinylbenzyl group derived from the compound having a vinylbenzyl group, the biphenyl skeleton is a structure of low polarity, and therefore contributes to a low dielectric constant and low dielectric loss tangent for the resin cured product obtained using the multifunctional vinylbenzyl compound, and in particular, enables a low dielectric loss tangent to be achieved in the high frequency band.

By incorporating the aromatic condensed ring in the multifunctional vinylbenzyl compound, the aromatic condensed ring functions as a rigid structure of low polarity, and therefore the resin cured product obtained using the multifunctional vinylbenzyl compound can contribute to a low dielectric loss tangent, particularly in the high frequency band.

### (Compound Having Aromatic Condensed Ring)

In the compound having an aromatic condensed ring, there are no particular limitations on the number of rings in the aromatic condensed ring, but a number from 2 to 5 rings is preferred. The aromatic condensed ring may be a condensed ring of two or more aromatic rings. Further, the aromatic condensed ring may be any ring structure having at least one aromatic ring, and may be a condensed ring of at least one aromatic ring and either one, or two or more, alicyclic hydrocarbons. The aromatic condensed ring may be substituted or unsubstituted. The substituent may be an alkyl group or the like. The substituent alkyl group may be a group of 1 to 30 carbon atoms, 1 to 12 carbon atoms, or 1 to 4 carbon atoms, and specific examples include a methyl group, ethyl group, n-propyl group, isopropyl group, n-butyl group, isobutyl group, tert-butyl group, and sec-butyl group.

The number of carbon atoms in the compound having the aromatic condensed ring is preferably within a range from 9 to 40, more preferably from 9 to 20, and even more preferably from 9 to 12.

Examples of the compound having an aromatic condensed ring include compounds having an indene ring, indane ring, phenanthrene ring, acenaphthylene ring, or fluorene ring or the like. At least one carbon atom of these aromatic condensed rings may have a substituent.

From the viewpoints of the dielectric characteristics and the flame retardancy, the compound having an aromatic condensed ring is preferably a compound having an indene ring or a derivative thereof, is more preferably a substituted or unsubstituted indene, and is even more preferably an unsubstituted indene.

In the reaction for the multifunctional vinylbenzyl compound, a single compound having an aromatic condensed ring may be used alone, or a combination of two or more such compounds may be used.

### (Compound Having a Biphenylene Group)

The unit derived from the compound having a biphenylene group introduces the biphenylene group into the multifunctional vinylbenzyl compound and can impart flame retardancy. Further, by incorporating the unit having a biphenylene group, the multifunctional vinylbenzyl compound is able to improve the dielectric characteristics for cured products of the resin composition.

The compound having a biphenylene group is preferably a compound having one biphenylene group and two reactive groups. For example, the compound having a biphenylene group is preferably a compound having one biphenylene group and one reactive group on each of the two benzene rings of the biphenylene group, and is more preferably a compound having one biphenylene group and reactive groups at position 4 and position 4′ of the biphenylene group. The reactive groups are preferably haloalkyl groups. The haloalkyl group preferably has 1 to 12 carbon atoms, more preferably 1 to 8 carbon atoms, and even more preferably 1 to 4 carbon atoms. The haloalkyl group is preferably a group in which at least one hydrogen atom of the alkyl group has been substituted with a halogen atom, wherein the halogen atom is preferably a chlorine atom or a bromine atom, and the number of halogen atom substitutions is preferably one. Specific examples of the haloalkyl group include a chloromethyl group, chloroethyl group, bromomethyl group, and bromoethyl group.

In the compound having a biphenylene group, the biphenylene group may be substituted or unsubstituted. The substituent may be an alkyl group or the like. The alkyl group substituent may have 1 to 30 carbon atoms, 1 to 12 carbon atoms, or 1 to 4 carbon atoms, and specific examples include a methyl group, ethyl group, n-propyl group, isopropyl group, n-butyl group, isobutyl group, tert-butyl group and sec-butyl group. The compound having a biphenylene group may contain a functional group containing a hetero atom as a substituent, but from the viewpoint of the dielectric characteristics, the compound preferably contains no functional groups containing a hetero atom. However, the compound having a biphenylene group may contain the halogen atoms included as the above reactive groups.

The compound having a biphenylene group differs from the compound having an aromatic condensed ring, and does not have an aromatic condensed ring.

The compound having a biphenylene group preferably includes a 4,4′-bis(haloalkyl)biphenyl. Examples of the compound having a biphenylene group include 4,4′-bis(chloromethyl)biphenyl, 3,4′-bis(chloromethyl)biphenyl, 3,3′-bis(chloromethyl)biphenyl, 4,4′-bis(bromomethyl)biphenyl, 3,4′-bis(bromomethyl)biphenyl, and 3,3′-bis(bromomethyl)biphenyl.

In the reaction for the multifunctional vinylbenzyl compound, a single compound having a biphenylene group may be used alone, or a combination of two or more such compounds may be used.

### (Compound Having a Vinylbenzyl Group)

The unit derived from the compound having a vinylbenzyl group provides the polymerizable functional group in the multifunctional vinylbenzyl compound, and contributes to the thermosetting properties. Further, by introducing a polymerizable functional group derived from the compound having a vinylbenzyl group, the multifunctional vinylbenzyl compound is able to contribute to the dielectric characteristics and flame retardancy of cured products of the resin composition.

In the multifunctional vinylbenzyl compound, the vinylbenzyl group of the compound having a vinylbenzyl group is preferably bonded to the aromatic condensed ring of the compound having an aromatic condensed ring, and more specifically, the vinylbenzyl group of the compound having a vinylbenzyl group is preferably bonded directly to a carbon atom on a ring of the aromatic condensed ring of the compound having an aromatic condensed ring.

From this viewpoint, the compound having a vinylbenzyl group is preferably a vinylbenzyl halide. The halogen atom of this vinylbenzyl halide is preferably a chlorine atom or a bromine atom. Examples of the vinylbenzyl halide include vinylbenzyl chloride and vinylbenzyl bromide, and vinylbenzyl chloride is preferred.

The vinylbenzyl group may be any one of an o-vinylbenzyl group, an m-vinylbenzyl group and a p-vinylbenzyl group, but is preferably an m-vinylbenzyl group or p-vinylbenzyl group, and is more preferably a p-vinylbenzyl group. A specific example is 4-vinylbenzyl chloride. In those cases where a compound containing a p-vinylbenzyl group is used, a mixture of the compound containing a p-vinylbenzyl group and a compound containing an m-vinylbenzyl group may also be used. In this mixture, the mass ratio between the compound containing a p-vinylbenzyl group and the compound containing an m-vinylbenzyl group may be within a range from 20:80 to 80:20, or from 40:60 to 60:40.

In the compound having a vinylbenzyl group, the vinylbenzyl group may be substituted or unsubstituted. The substituent may be an alkyl group or the like. The alkyl group substituent may have 1 to 30 carbon atoms, 1 to 12 carbon atoms, or 1 to 4 carbon atoms, and specific examples include a methyl group, ethyl group, n-propyl group, isopropyl group, n-butyl group, isobutyl group, tert-butyl group and sec-butyl group.

The compound having a vinylbenzyl group differs from both the compound having an aromatic condensed ring and the compound having a biphenylene group, and does not have an aromatic condensed ring or a biphenylene group.

In the reaction for the multifunctional vinylbenzyl compound, a single compound having a vinylbenzyl group may be used alone, or a combination of two or more such compounds may be used.

There are no particular limitations on the method used for reacting the compound having an aromatic condensed ring, the compound having a biphenylene group and the compound having a vinylbenzyl group. For example, the reaction may be conducted by mixing the compound having an aromatic condensed ring, the compound having a biphenylene group and the compound having a vinylbenzyl group, and then heating and stirring the mixture if necessary. The reaction may be conducted in a solvent, and there are no particular limitations on the solvent, which may, for example, be selected appropriately from among the organic solvents listed below for use as the solvent of the resin composition described below. The reaction temperature is preferably within a range from 20 to 80° C. During the reaction, additives such as a phase transfer catalyst and/or polymerization inhibitor may also be added to the reaction mixture.

A phase transfer catalyst is used by including an organic solvent and water in the reaction system. An organic solvent that does not exhibit miscibility with water is preferred, and examples include toluene and the like. Examples of the phase transfer catalyst include quaternary ammonium salts such as tetra-n-butylammonium chloride, tetra-n-butylammonium bromide, tetraethylammonium chloride, tetraethylammonium bromide, tetrapropylammonium chloride, tetrapropylammonium bromide, benzyltrimethylammonium chloride, benzyltrimethylammonium bromide, benzyltributylammonium chloride, benzyltributylammonium bromide, benzyldimethyltetradecylammonium chloride, tricaprylmethylammonium chloride, tetradecyltrimethylammonium bromide, hexadecyltrimethylammonium bromide, trioctylmethylammonium chloride, and tetra-n-butylammonium hydrogensulfate; and quaternary phosphonium salts such as tetra-n-butylphosphonium chloride, tetra-n-butylphosphonium bromide, tetraphenylphosphonium chloride, tetraphenylphosphonium bromide, benzyltriphenylphosphonium chloride, and benzyltriphenylphosphonium bromide.

A single phase transfer catalyst may be used alone, or a combination of two or more phase transfer catalysts may be used.

A polymerization inhibitor is added to the reaction system to adjust the degree of polymerization of the multifunctional vinylbenzyl compound. Examples of the polymerization inhibitor include hydroquinone, methylhydroquinone, tert-butylhydroquinone, 2,6-di-tert-butylhydroquinone, 2,5-di-tert-butylhydroquinone, hydroquinone monomethyl ether, 1,4-benzoquinone, 2-tert-butyl-1,4-benzoquinone, 2-tert-butylphenol, 2,4-di-tert-butylphenol, 2,6-di-tert-butylphenol, cresol, catechol, 4-tert-butylcatechol, pyrogallol, 4-methoxyphenol, thiodiphenylamine, phenothiazine, 3,7-dioctylphenothiazine, 3,7-dicumylphenothiazine, 2,2,6,6-tetramethylpiperidine-1-oxyl, 4-hydroxy-2,2,6,6-tetramethylpiperidine-1-oxyl, 4-benzoyloxy-2,2,6,6-tetramethylpiperidine-1-oxyl, and bis(2,2,6,6-tetramethyl-1-piperidinyloxy-4-yl) sebacate.

Further, from the viewpoint of reaction control, the reaction may be conducted under basic conditions. For example, a basic compound may be added to the mixture. Examples of this basic compound include alkali metal hydroxides, and alkali metal alkoxides, and specific examples include sodium hydroxide and the like.

The product obtained from the reaction may, if necessary, by purified using conventional methods such as concentration, re-precipitation, or washing or the like.

As a result of the reaction between the compound having an aromatic condensed ring, the compound having a biphenylene group and the compound having a vinylbenzyl group, the multifunctional vinylbenzyl compound preferably has a partial structure in which the unit (A) having the aromatic condensed ring and the unit (B) having the biphenylene group are bonded together in an ABA arrangement. In this ABA partial structure, it is preferable that the vinylbenzyl group is bonded to the aromatic condensed ring of at least one of the A units. For example, the multifunctional vinylbenzyl compound is preferably a compound represented by ABA, wherein a vinylbenzyl group is bonded to each of the two aromatic condensed rings within the A units. With these types of structures, the dielectric characteristics can be improved, a particularly low dielectric loss tangent can be achieved, and favorable flame retardancy can also be obtained.

The multifunctional vinylbenzyl compound may be obtained by reacting the compound having an aromatic condensed ring the compound having a biphenylene group in equimolar amounts, but may also be obtained by conducting the reaction using a molar ratio in which for each 100 parts by mol of the compound having an aromatic condensed ring, the amount of the compound having a biphenylene group is not more than 100 parts by mol, not more than 80 parts by mol, not more than 60 parts by mol, or 50 parts by mol or less. More specifically, the multifunctional vinylbenzyl compound may be obtained by conducting the reaction using a molar ratio in which for each 100 parts by mol of the compound having an aromatic condensed ring, the amount of the compound having a biphenylene group is within a range from 10 to 100 parts by mol, from 20 to 80 parts by mol, from 30 to 60 parts by mol, or from 40 to 50 parts by mol. By increasing the proportion of the compound having a biphenylene group in the reaction the degree of polymerization can be increased, but that proportion may also be restricted from the viewpoint of reaction acceleration. In those cases where the molecular weight of the multifunctional vinylbenzyl compound is low, the terminal structures are preferably units derived from the compound having an aromatic condensed ring. A molar ratio that satisfies the above ranges is also preferred from this perspective.

The multifunctional vinylbenzyl compound may be obtained by reacting the compound having an aromatic condensed ring the compound having a vinylbenzyl group in equimolar amounts, but may also be obtained by conducting the reaction using a molar ratio in which for each 100 parts by mol of the compound having an aromatic condensed ring, the amount of the compound having a vinylbenzyl group is not more than 200 parts by mol, not more than 140 parts by mol, not more than 120 parts by mol, or 100 parts by mol or less. More specifically, the multifunctional vinylbenzyl compound may be obtained by conducting the reaction using a molar ratio in which for each 100 parts by mol of the compound having an aromatic condensed ring, the amount of the compound having a vinylbenzyl group is within a range from 50 to 200 parts by mol, from 60 to 140 parts by mol, from 80 to 120 parts by mol, or from 90 to 100 parts by mol. In the reaction, by introducing either one vinylbenzyl group, or two or more vinylbenzyl groups per aromatic condensed ring, more favorable curing acceleration can be achieved for the resin composition.

### Other Embodiment

Another embodiment provides a multifunctional vinylbenzyl compound containing a unit having an aromatic condensed ring and a unit having a biphenylene group, wherein the multifunctional vinylbenzyl compound has a structure in which the aromatic condensed rings are respectively bonded, either directly or via a linking group, to two carbon atoms on the rings of the biphenylene group, with the linking group being a divalent hydrocarbon group, and also has a vinylbenzyl group bonded directly to a carbon atom on a ring of the aromatic condensed ring.

In this multifunctional vinylbenzyl compound, it is preferable that the unit having the aromatic condensed ring has an indene ring, and has a vinylbenzyl group bonded directly to at least one of the carbon atoms at position 1, position 2 and position 3 of the indene ring.

The multifunctional vinylbenzyl compound according to this embodiment is not limited by the synthesis method used, and may be obtained, for example, by reacting the abovementioned compound having an aromatic condensed ring, compound having a biphenylene group, and compound having a vinylbenzyl group.

### Yet Another Embodiment

Yet another embodiment provides a multifunctional vinylbenzyl compound represented by formula (1) shown below.

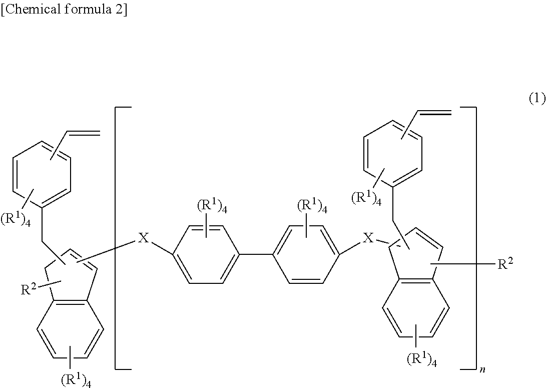

In formula (1):
each R¹ independently represents a monovalent group of 1 to 30 carbon atoms or a hydrogen atom,
each R² independently represents a monovalent group of 1 to 30 carbon atoms, a hydrogen atom, or a bonding location with another structure,
each X independently represents an alkylene group of 1 to 4 carbon atoms or a single bond, and
n is an integer of 1 or greater.

The multifunctional vinylbenzyl compound according to this embodiment is not limited by the synthesis method used, and for example, as already outlined above, may be obtained by reacting a substituted or unsubstituted indene, a substituted or unsubstituted 4,4′-bis(haloalkyl)biphenyl, and a substituted or unsubstituted vinylbenzyl halide. The substituents are the groups represented by R¹ and R² in formula (1).

In formula (1), each R¹ independently represents a monovalent group of 1 to 30 carbon atoms or a hydrogen atom. The monovalent group represented by R¹ is preferably a saturated or unsaturated, chain-like or cyclic hydrocarbon group. The monovalent group represented by R¹ may have 1 to 30 carbon atoms, 1 to 12 carbon atoms, or 1 to 4 carbon atoms. Specific examples of the monovalent group represented by R¹ include alkyl groups such as a methyl group, ethyl group, n-propyl group, isopropyl group, n-butyl group, isobutyl group, tert-butyl group, and sec-butyl group. The plurality of R¹ groups in formula (1) may all be the same, or some or all of the groups may be different. In formula (1), some or all of the R¹ groups are preferably hydrogen atoms.

In formula (1), each R² independently represents a monovalent group of 1 to 30 carbon atoms, a hydrogen atom, or a bonding location with another structure. In other words, each R² may independently represent a group represented by R¹. Alternatively, R² may represent a bonding site with a unit having a biphenyl group, or a unit having a vinylbenzyl group or the like. The plurality of R² groups in formula (1) may all be the same, or some or all of the groups may be different. In formula (1), one or both of the R² groups preferably each represent a group represented by R¹, and more preferably a hydrogen atom.

In formula (1), each X independently represents an alkylene group of 1 to 4 carbon atoms or a single bond. Examples of the alkylene group include a methylene group, ethylene group, trimethylene group, isopropylene group, n-butylene group, isobutylene group, tert-butylene group, and sec-butylene group. The plurality of X groups in formula (1) may all be the same, or some or all of the groups may be different. In formula (1), some or all of the X groups preferably represent a methylene group or a single bond, and more preferably a methylene group.

In formula (1), n represents an integer of 1 or greater. Further, n represents an integer that is preferably within a range from 1 to 10, more preferably from 1 to 5, and even more preferably from 1 to 4. The value of n may be 1. Further, in formula (1), n may be an integer that has been determined appropriately in accordance with the weight average molecular weight (Mw) of the multifunctional vinylbenzyl compound described below.

In formula (1), the bonding site between each indene ring and vinylbenzyl group is preferably position 1 of the indene ring. Further, the bonding site between each indene ring and X group is preferably position 1 or position 2 of the indene ring. Further, the vinylbenzyl groups may be any one of o-vinylbenzyl groups, m-vinylbenzyl groups and p-vinylbenzyl groups, but are preferably p-vinylbenzyl groups. In formula (1), it is preferable that some or all of the vinylbenzyl groups are p-vinylbenzyl groups.

The multifunctional vinylbenzyl compound represented by formula (1) is preferably a compound containing the partial structure represented by formula (2) shown below.

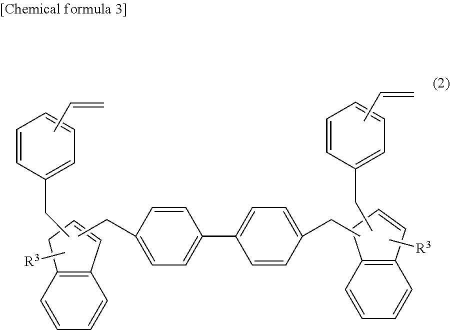

In formula (2), each R³ independently represents a monovalent group of 1 to 30 carbon atoms, a hydrogen atom, or a bonding location with another structure. Details relating to R³ are as described above for R² in formula (1). Other structures are also as described above in formula (1).

The plurality of R³ groups in formula (2) may all be the same, or some or all of the groups may be different. In formula (2), one or both of the R³ groups preferably each represent a group represented by R¹ of formula (1), and more preferably a hydrogen atom.

The multifunctional vinylbenzyl compound represented by formula (1) contains a repeating unit containing a unit having the aromatic condensed ring and a unit having the biphenylene group, and therefore has a molar ratio in which for each 100 parts by mol of the unit having an aromatic condensed ring, the amount of the unit having a biphenylene group may be within a range from 50 to 150 parts by mol, from 50 to 100 parts by mol, from 50 to 80 parts by mol, or from 50 to 60 parts by mol. In those cases where the molecular weight of the multifunctional vinylbenzyl compound is low, the terminal structures are preferably units derived from the compound having an aromatic condensed ring. A molar ratio that satisfies the above ranges is also preferred from this perspective.

The multifunctional vinylbenzyl compound represented by formula (1) contains a structure in which a unit having the vinylbenzyl group is bonded to a unit having the aromatic condensed ring, and therefore has a molar ratio in which for each 100 parts by mol of the unit having an aromatic condensed ring, the amount of the unit having a vinylbenzyl group may be within a range from 50 to 200 parts by mol, from 100 to 150 parts by mol, or from 100 to 120 parts by mol.

The weight average molecular weight (Mw) of the multifunctional vinylbenzyl compound is described below.

The weight average molecular weight (Mw) of the multifunctional vinylbenzyl compound may be 100,000 or lower, 50,000 or lower, 10,000 or lower, 5,000 or lower, or 2,000 or lower. Within these ranges, more favorable solvent solubility and coating properties can be obtained for the resin composition, and more favorable moldability and flexibility can be achieved for a coating film, semi-cured product or cured product.

The weight average molecular weight (Mw) of the multifunctional vinylbenzyl compound may be at least 400, at least 500, at least 800, or 1,000 or higher. Within these ranges, more favorable solvent solubility and coating properties can be obtained for the resin composition, and more favorable moldability and flexibility can be achieved for a coating film, semi-cured product or cured product.

For example, the weight average molecular weight (Mw) of the multifunctional vinylbenzyl compound may be within a range from 400 to 100,000, from 400 to 50,000, from 500 to 10,000, from 800 to 5,000, or from 1,000 to 2,000.

### [Resin Composition]

The resin composition according to one embodiment contains the multifunctional vinylbenzyl compound. Details relating to the multifunctional vinylbenzyl compound are as described above.

The resin composition may contain a multifunctional vinylbenzyl compound obtained by a reaction between a compound having an aromatic condensed ring, a compound having a biphenylene group, and a compound having a vinylbenzyl group. This multifunctional vinylbenzyl compound may be included as a reaction product. In such cases, the resin composition may contain a plurality of types of multifunctional vinylbenzyl compounds with differing molecular weights and molecular structures.

In the resin composition, there are no particular limitations on the synthesis method for the multifunctional vinylbenzyl compound, and the resin composition may contain a multifunctional vinylbenzyl compound containing a unit having an aromatic condensed ring and a unit having a biphenylene group, and having a structure in which the aromatic condensed rings are respectively bonded, either directly or via a linking group, to two carbon atoms on the rings of the biphenylene group, with the linking group being a divalent hydrocarbon group, and also having a vinylbenzyl group bonded directly to a carbon atom on the ring of the aromatic condensed ring, or the resin composition may contain a compound represented by formula (1).

A resin composition containing this type of multifunctional vinylbenzyl compound is able to impart excellent dielectric characteristics and flame retardancy to the cured products of the composition.

In addition to the multifunctional vinylbenzyl compound, the resin composition may also contain at least one of a thermosetting resin and a thermoplastic resin as another resin component.

Examples of the thermosetting resin include epoxy resins, maleimide resins, modified polyphenylene ether resins, phenol resins, polyimide resins, cyanate resins, isocyanate resins, benzoxazine resins, oxetane resins, amino resins, unsaturated polyester resins, allyl resins, dicyclopentadiene resins, silicone resins, triazine resins, and melamine resins. The thermosetting resin is capable of undergoing an increase in molecular weight and/or a curing reaction upon heating, if necessary in the presence of a polymerization initiator or the like. A single thermosetting resin may be used alone, or a combination of two or more thermosetting resins may be used.

An elastomer may be included as a thermoplastic resin. Examples of the elastomer include diene-based elastomers, olefin-based elastomers, polysulfide-based elastomers, silicone-based elastomers, fluorine-based elastomers, urethane-based elastomers, and ether-based elastomers. More specific examples include diene-based elastomers such as styrene-butadiene rubber (SBR), butadiene rubber (BR), styrene-isoprene rubber, isoprene rubber (IR), chloroprene rubber (CR), and acrylonitrile-butadiene rubber (NBR). Specific examples of the olefin-based elastomers include butyl rubber (IIR), ethylene-propylene rubber, ethylene-vinyl acetate rubber, chlorosulfonated polyethylene, and acrylic rubber. These elastomers may be either unhydrogenated or hydrogenated. A single elastomer may be used alone, or a combination of two or more elastomers may be used.

Relative to the total mass of the resin component in the resin composition, the mass of the multifunctional vinylbenzyl compound may be within a range from 10 to 100% by mass, from 30 to 90% by mass, from 50 to 80% by mass, or from 60 to 80% by mass. In this description, the total mass of the resin component in the resin composition means the combined mass of polymers, and polymerizable oligomers and monomers.

Relative to the total mass of the resin component in the resin composition, the combined mass of the multifunctional vinylbenzyl compound and any other thermosetting resins may be within a range from 10 to 100% by mass, from 30 to 90% by mass, from 50 to 80% by mass, or from 60 to 80% by mass.

Relative to the total mass of the resin component in the resin composition, the combined mass of all thermoplastic resins may be within a range from 1 to 90% by mass, from 10 to 70% by mass, or from 20 to 50% by mass.

Relative to the total mass of the resin composition, the total mass of the resin component may be within a range from 10 to 80% by mass, from 30 to 70% by mass, or from 40 to 60% by mass.

The resin composition may be a solventless composition, or may contain a solvent. The solvent can adjust the viscosity of the resin composition and further improve the coating properties. An organic solvent is preferred as the solvent.

Examples of the organic solvent include alcohol-based solvents such as ethanol, propanol, butanol, methyl cellosolve, ethylene glycol monobutyl ether, and propylene glycol monomethyl ether; ketone-based solvents such as acetone, methyl ethyl ketone, methyl isobutyl ketone, and cyclohexanone; ether-based solvents such as tetrahydrofuran; aromatic hydrocarbon-based solvents such as toluene, xylene, and mesitylene; nitrogen atom-containing solvents such as dimethylformamide, dimethylacetamide, and N-methylpyrrolidone; sulfur atom-containing solvents such as dimethyl sulfoxide; and ester-based solvents such as γ-butyrolactone. A single organic solvent may be used alone, or a combination of two or more organic solvents may be used.

In those cases where the resin composition contains a solvent, the mass of the solid component, which includes the solid mass of all of the components other than the solvent, relative to the total mass of the resin composition, may be within a range from 10 to 80% by mass, from 30 to 70% by mass, or from 40 to 60% by mass. Compounds containing a polymerizable functional group are not included in the solvent.

The resin composition may contain an inorganic filler as an optional component. Examples of the inorganic filler include silica (SiO₂), alumina (Al₂O₃), titanium oxide, barium titanate, strontium titanate, potassium titanate, calcium titanate, aluminum carbonate, magnesium hydroxide, aluminum hydroxide, aluminum silicate, calcium carbonate, calcium silicate, magnesium silicate, silicon nitride, boron nitride, aluminum borate, silicon carbide, mica, beryllia, clay, and talc.

There are no particular limitations on the shape and size of the inorganic filler. For example, the average particle size of the inorganic filler may be within a range from 0.01 to 20 μm, or from 0.1 to 10 μm. In this description, the average particle size of an inorganic filler represents the particle size corresponding with a cumulative value of 50% in a volume-based particle size distribution produced using a laser diffraction/scattering method.

A single inorganic filler may be used alone, or a combination of two or more inorganic fillers may be used.

The amount of the inorganic filler, relative to the total solid fraction of the resin composition, may be within a range from 10 to 80% by volume, from 30 to 70% by volume, or from 50 to 60% by volume.

The resin composition may also contain a curing catalyst to accelerate curing of the multifunctional vinylbenzyl compound.

A radical polymerization initiator may be used as the curing catalyst. The radical polymerization initiator may be a thermal radical polymerization initiator or a photo radical polymerization initiator, but a thermal radical polymerization initiator is preferred. There are no particular limitations on the radical polymerization initiator, and examples include azo-based polymerization initiators and organic peroxide-based polymerization initiators.

The amount used of the curing catalyst may be adjusted as appropriate, and for example, may be within a range from 0.01 to 5 parts by mass, from 0.1 to 4 parts by mass, or from 0.5 to 2 parts by mass per 100 parts by mass of the multifunctional vinylbenzyl compound.

The resin composition may also contain a flame retardant.

Examples of the flame retardant include phosphorus-based flame retardants, metal hydrates, and halogen-based flame retardants. From the viewpoint of potential environmental issues, a phosphorus-based flame retardant is preferred.

The phosphorus-based flame retardant may be either an inorganic system phosphorus-based flame retardant or an organic system phosphorus-based flame retardant, but an organic system phosphorus-based flame retardant is preferred.

Examples of inorganic system phosphorus-based flame retardants include red phosphorus; ammonium phosphates such as monoammonium phosphate, diammonium phosphate, triammonium phosphate, and ammonium polyphosphate; inorganic system nitrogen-containing phosphorus compounds such as phosphoramide; phosphoric acid; and phosphine oxide.

Examples of organic system phosphorus-based flame retardants include aromatic phosphate esters, mono-substituted phosphonic acid diesters, and di-substituted phosphinic acid esters; and metal salts of di-substituted phosphonic acids, organic nitrogen-containing phosphorus compounds, and cyclic organic phosphorus compounds. Examples of the metal salts of di-substituted phosphonic acids include lithium salts, sodium salts, potassium salts, calcium salts, magnesium salts, aluminum salts, titanium salts, and zinc salts.

The amount of the flame retardant may be within a range from 0.1 to 30 parts by mass, from 1 to 20 parts by mass, or from 5 to 10 parts by mass, per 100 parts by mass of the total mass of the resin component in the resin composition.

The resin composition may also contain other additives besides those described above, provided the effects of the present invention are not impaired. Examples of these other additives include curing accelerators, antioxidants, thermal stabilizers, antistatic agents, ultraviolet absorbers, pigments, colorants, and lubricants and the like.

There are no particular limitations on the method used for producing the resin composition. In one example of the production method, the resin composition can be obtained by adding any optional components as required to the multifunctional vinylbenzyl compound, and then mixing the resulting mixture. More specifically, the resin composition can be obtained by dissolving or dispersing the multifunctional vinylbenzyl compound in a solvent, and then adding and mixing any additives and the like as required. There are no particular limitations on conditions such as the order in which components are added and mixed, the temperature, and the mixing time and the like, and these conditions may be set appropriately in accordance with the types of raw materials, the production scale, and the production apparatus and the like.

A cured product of the resin composition has a residual mass ratio following heating, represented by the mass following heating at 800° C. relative to the mass prior to heating, that is preferably at least 25% by mass, more preferably at least 28% by mass, and even more preferably 30% by mass or higher. A value within these ranges enables a product of excellent flame retardancy to be provided.

In particular, the cured product of a resin composition containing the multifunctional vinylbenzyl compound but containing no other solid components preferably has a residual mass ratio following heating that falls within the above range.

In this description, the residual mass ratio following heating of a cured product of the resin composition can be determined by measuring the change in mass when the cured product of the resin composition is heated to 800° C. under conditions including a stream of nitrogen (100 ml·min⁻¹) and a rate of temperature increase of 10° C.·min⁻¹. For example, a TG/DTA apparatus manufactured by Hitachi High-Tech Science Corporation may be used as the measurement apparatus.

The test piece for measuring the residual mass ratio following heating is prepared by curing the resin composition to achieve a C-stage state as described in JIS K 6800 (1985). Specifically, a resin powder is prepared by semi-curing the resin composition to achieve a B-stage state and then grinding the semi-cured product, and this resin powder is then placed in a molding die and subjected to vacuum heated compression molding under conditions including a temperature of 150° C., a pressure of 1.5 to 2.0 MPa, and a molding time of 120 minutes, before additional heated molding is conducted at 180° C. for 300 minutes to prepare a molded sheet-like cured product with a thickness of 1 mm.

The cured product of the resin composition has a dielectric loss tangent (Df) at 25° C. and 10 GHz that is preferably not more than 0.0020, more preferably not more than 0.0019, and even more preferably 0.0017 or lower. The dielectric loss tangent (Df) at 25° C. and 10 GHz for the cured product of the resin composition is preferably as low as possible, and although there is no particular limitation on the lower limit for this value, considering the balance with other physical properties, the dielectric loss tangent may be, for example, 0.0001 or higher, 0.0005 or higher, or 0.0010 or higher.

For example, at a measurement temperature of 25° C., the cured product of the resin composition preferably has a dielectric loss tangent (Df) at a frequency of 10 GHz within a range from 0.0001 to 0.0020, from 0.0005 to 0.0019, or from 0.0010 to 0.0017.

The cured product of the resin composition has a dielectric constant (Dk) at 25° C. and 10 GHz that is preferably not more than 4.0, more preferably not more than 3.0, even more preferably not more than 2.7, and still more preferably 2.6 or lower. The dielectric constant (Dk) at 25° C. and 10 GHz for the cured product of the resin composition is preferably as low as possible, and although there is no particular limitation on the lower limit for this value, considering the balance with other physical properties, the dielectric constant may be, for example, at least 2.3, or 2.4 or higher.

For example, at a measurement temperature of 25° C., the cured product of the resin composition preferably has a dielectric constant (Dk) at a frequency of 10 GHz within a range from 2.3 to 4.0, from 2.3 to 3.0, from 2.4 to 2.7, or from 2.4 to 2.6.

In particular, the cured product of a resin composition containing the multifunctional vinylbenzyl compound but containing no other solid components preferably has a dielectric loss tangent (Df) and a dielectric constant (Dk) at 25° C. and 10 GHz that fall within the above ranges.

In this description, the values for the dielectric loss tangent (Df) and the dielectric constant (Dk) are measured in the 10 GHz band at 25° C. in accordance with the Split Post Dielectric Resonator method. A “PNA Network Analyzer N5222B” (product name) manufactured by Agilent Technologies, Inc. may be used as the measurement apparatus.

The test piece for measuring the dielectric loss tangent (Df) and the dielectric constant (Dk) is prepared by curing the resin composition to achieve a C-stage state as described in JIS K 6800 (1985). Specifically, a resin powder is prepared by semi-curing the resin composition to achieve a B-stage state and then grinding the semi-cured product, and this resin powder is then placed in a molding die and subjected to vacuum heated compression molding under conditions including a temperature of 150° C., a pressure of 1.5 to 2.0 MPa, and a molding time of 120 minutes, before additional heated molding is conducted at 180° C. for 300 minutes to prepare a molded sheet-like cured product with a thickness of 1 mm.

### [Prepreg]

One embodiment of the invention provides a prepreg formed using the resin composition and a fibrous substrate. Details regarding the resin composition are as described above.

A prepreg means a state in which the fibrous substrate is impregnated with the resin composition. In the prepreg, the resin composition may exist in an uncured state, or the resin composition may exist in a partially or completely semi-cured state. A cured product can be obtained, for example, by using this prepreg to assemble a molded item such as a laminate, and then curing the molded item by conducting a heat treatment or the like.

The prepreg can be obtained, for example, by applying the resin composition to a fibrous substrate and then drying the resulting coated product. In a different method, the prepreg can be obtained by impregnating and coating the fibrous substrate with the resin composition, and then drying the fibrous substrate that has been impregnated with the resin composition. The drying process is preferably conducted at a temperature at least as high as the temperature at which volatile components such as solvents contained in the resin composition can be removed, and depending on the application, may be at least as high as the temperature that results in semi-curing of the resin composition. Further, the drying process may be adjusted so that the resin composition does not undergo complete curing. From this type of viewpoint, the drying temperature may be within a range from 80 to 200° C., and the drying time may be adjusted within a range from 1 to 30 minutes in accordance with factors such as the drying temperature, the drying device, and the scale of the drying device.

In this description, one indicator of a semi-cured product is the B-stage state described in JIS K 6800 (1985).

The fibrous substrate may be a woven substrate, a knitted substrate, or a non-woven substrate. The fibrous substrate may be provided in a form such as a chopped-strand mat or a roving or the like. The fiber material may be either inorganic fiber or organic fiber. Examples of inorganic fiber include glass fiber and carbon fiber. Specific examples of glass fiber include E-glass, NE-glass, D-glass, S-glass and Q-glass. Examples of organic fiber include polyimide, polyester, and tetrafluoroethylene. The fibrous substrate may contain only one of these types of fiber, or may be a mixed fiber containing two or more types of fiber. From the viewpoints of the dielectric characteristics and flame retardancy, the fibrous substrate is preferably an inorganic fiber, and more preferably a glass fiber. A prepreg that uses an inorganic fiber also exhibits heat resistance and dimensional stability.

The fibrous substrate may be selected appropriately in accordance with the intended application for the prepreg, but a sheet-like fibrous substrate is preferred. The sheet-like fibrous substrate may be, for example, any of the various sheet-like fibrous substrates used in conventional laminates for electrical insulation materials. Although there are no particular limitations on the thickness of the sheet-like fibrous substrate, for example, a thickness of 0.02 to 0.5 mm is preferred. Here, the thickness is determined by measuring the thickness at 5 equally spaced points across the entire surface of the sheet-like fibrous substrate, and then calculating the arithmetic mean of the 5 measurements.

In the prepreg, the total mass of the thermosetting resins including the multifunctional vinylbenzyl compound, and any thermoplastic resins, relative to the total mass of the prepreg, may be within a range from 20 to 90% by mass, or from 30 to 80% by mass. Within these ranges, impregnation and coating of the resins into the fibrous substrate of the prepreg can be achieved more easily. Further, the step of assembling the prepreg into a molded item and then conducting curing can also be performed more easily.

### [Resin Film]

One embodiment of the invention provides a resin film formed using the resin composition. Details regarding the resin composition are as described above.

A resin film means a state in which the resin composition has been molded into film form. In the resin film, the resin composition may exist in an uncured state, or the resin composition may be partially or completely in a semi-cured state. A cured product can then be obtained by curing this resin film by conducting a heat treatment or the like.

The resin film can be obtained, for example, by applying the resin composition to a coating target material and then drying the resulting coated product. The drying process may be conducted, for example, in the same manner as that described above in the method for producing a prepreg. Following drying of the resin film on the coating target material, the product may be provided a combination of the resin film and the coating target material. For example, in this method, the resin film may be provided to form an insulating layer or the like on a coating target material in an electronic device or the like. In a different method, following drying of the resin film on the coating target material, the resin film may be detached from the coating target material and provided as a resin film product.

The coating target material may be either an inorganic substrate or an organic substrate, and examples include glass substrates, metal substrates such as metal foils and metal sheets, plastic substrates such as plastic sheets and plastic films, and paper substrates. The coating target material may be a fibrous substrate as described above in relation to the prepreg, or may be a prepreg. In order to enable the resin film to be detached from the coating target material, a coating target material having a release layer formed on the surface may also be used.

### [Metal-Clad Laminate]

One embodiment of the invention provides a metal-clad laminate formed using the prepreg and a metal foil. Another embodiment provides a metal-clad laminate containing a resin cured product layer and a metal foil. The resin cured product layer may be a cured product of the resin composition or a cured product of the prepreg. Details regarding the resin composition and the prepreg are as described above.

The metal-clad laminate preferably contains a resin cured product layer containing the resin cured product, and a metal foil formed on at least one surface of the resin cured product layer. The resin cured product layer is a layer containing a cured product of the resin composition, and may be a cured product of the prepreg described above. Examples of more useful applications include laminates in which a metal foil is formed on at least one surface of the cured product of a prepreg, and a laminate in which a metal foil is formed on both surfaces of the cured product of the prepreg is particularly preferred. The metal-clad laminate may be produced by forming a metal foil on at least one surface of a single sheet-like prepreg, or may be produced by laminating two or more sheet-like prepregs, and then forming the metal foil on at least one of the outermost surfaces of the laminated prepregs. In a particularly useful application, the metal-clad laminate is produced by laminating two or more sheet-like prepregs, and then forming metal foils on both surfaces of the resulting laminate. Specifically, the metal-clad laminate can be produced, for example, by arranging a metal foil on one surface or both surfaces of a sheet-like prepreg, and subsequently conducting heated compression molding. This heated compression molding causes the curing reaction of the sheet-like prepreg to proceed, yielding a metal-clad laminate containing a cured product of the prepreg. In the heated compression molding, a single prepreg may be used alone, or two or more prepregs may be laminated together. The heated compression molding may be conducted using, for example, an autoclave molding machine, a multistage press, a multistage vacuum press, or a continuous molding machine or the like. There are no particular limitations on the heated compression molding conditions, and the process may be conducted, for example, at a temperature of 100 to 300° C. for a period of 10 to 300 minutes at a pressure of 1.5 to 5 MPa.

There are no particular limitations on the metal of the metal foil, and examples include copper, nickel, aluminum, gold, silver, platinum, molybdenum, ruthenium, tungsten, iron, titanium and chromium, as well as alloys and the like containing two or more of these metal elements. From an industrial perspective, the metal may be simple metals of copper, nickel or aluminum. By using copper as the copper foil, a copper-clad laminate can be provided.

The dielectric characteristics of the resin cured product in a state where the metal foil of the assembled metal-clad laminate has been removed (hereinafter also referred to as simply the dielectric characteristics of the metal-clad laminate) are preferably as described below. By using a resin composition containing the multifunctional vinylbenzyl compound according to one embodiment of the invention, a metal-clad laminate having excellent dielectric characteristics can be provided.

The dielectric loss tangent (Df) of the metal-clad laminate at a measurement temperature of 25° C. and a frequency of 10 GHz is preferably within a range from 0.0001 to 0.0020, from 0.0005 to 0.0019, or from 0.0010 to 0.0017.

The dielectric constant (Dk) of the metal-clad laminate at a measurement temperature of 25° C. and a frequency of 10 GHz is preferably within a range from 2.3 to 4.0, from 2.3 to 3.0, from 2.4 to 2.7, or from 2.4 to 2.6.

The measurements of the dielectric loss tangent (Df) and the dielectric constant (Dk) of the metal-clad laminate may be conducted in the same manner as the measurements of the dielectric loss tangent (Df) and the dielectric constant (Dk) of the cured product of the resin composition described above.

### [Printed Wiring Board]

One embodiment of the invention provides a printed wiring board containing a cured product of the resin composition. Details regarding the resin composition are as described above.

In the printed wiring board, the cured product of the resin composition can be produced using the resin composition, a prepreg, a resin film, a metal-clad laminate, or a combination thereof. For example, a printed wiring board can be provided by using a metal-clad laminate containing a cured product of the resin composition as a substrate for the printed wiring board, and then conducting conductive circuit formation using conventional methods. Details regarding the prepreg, the resin film and the metal-clad laminate are as described above. The printed wiring board may be either a single-layer printed wiring board or a multilayer printed wiring board.

### [Semiconductor Package]

One embodiment of the invention provides a semiconductor package containing a printed wiring board containing a resin cured product and a semiconductor element, wherein the resin cured product is a cured product of the above resin composition. Details regarding the resin composition are as described above. Details regarding the cured product of the resin composition and the printed wiring board are also as described above. The semiconductor package can be produced, for example, by using conventional methods to mount a semiconductor element and/or memory or the like onto a printed wiring board. The resin cured product may also be used as an insulating material or a sealing material or the like in the semiconductor package.

Examples of the embodiments are described below. The present invention is not limited to the following embodiments.
<1> A multifunctional vinylbenzyl compound obtained by a reaction between a compound having an aromatic condensed ring, a compound having a biphenylene group, and a compound having a vinylbenzyl group.
<2> The multifunctional vinylbenzyl compound according to <1>, wherein the compound having an aromatic condensed ring includes indene.
<3> The multifunctional vinylbenzyl compound according to <1> or <2>, wherein the compound having a biphenylene group includes a 4,4′-bis(haloalkyl)biphenyl.
<4> The multifunctional vinylbenzyl compound according to any one of <1> to <3>, wherein the compound having a vinylbenzyl group includes a vinylbenzyl halide.
<5> A multifunctional vinylbenzyl compound containing a unit having an aromatic condensed ring and a unit having a biphenylene group, wherein
   the multifunctional vinylbenzyl compound has a structure in which the aromatic condensed rings are respectively bonded, either directly or via a linking group, to two carbon atoms on the rings of the biphenylene group, with the linking group being a divalent hydrocarbon group, and
   also has a vinylbenzyl group bonded directly to a carbon atom on a ring of the aromatic condensed ring.
<6> The multifunctional vinylbenzyl compound according to <5>, wherein
   the unit having an aromatic condensed ring has an indene ring, and
   has the vinylbenzyl group bonded directly to at least one of the carbon atoms at position 1, position 2 and position 3 of the indene ring.
<7> A multifunctional vinylbenzyl compound represented by formula (1) shown below.

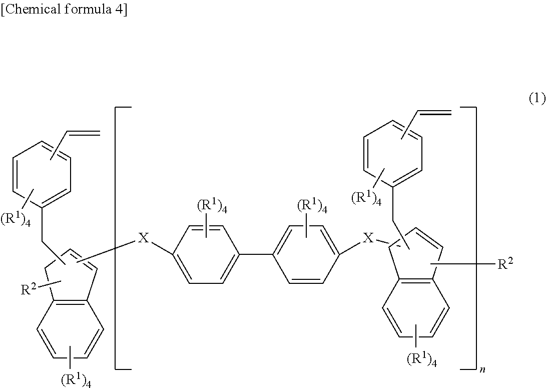

In formula (1):
each R¹ independently represents a monovalent group of 1 to 30 carbon atoms or a hydrogen atom,
each R² independently represents a monovalent group of 1 to 30 carbon atoms, a hydrogen atom, or a bonding location with another structure,
each X independently represents an alkylene group of 1 to 4 carbon atoms or a single bond, and
n is an integer of 1 or greater.
<8> The multifunctional vinylbenzyl compound according to <7>, containing a partial structure represented by formula (2) shown below.

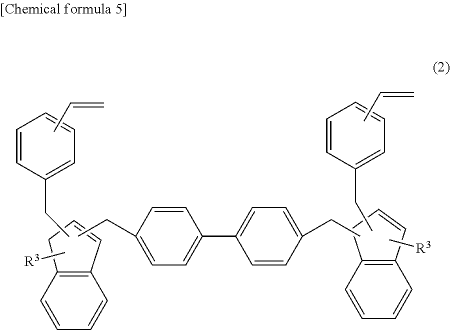

In formula (2), each R³ independently represents a monovalent group of 1 to 30 carbon atoms, a hydrogen atom, or a bonding location with another structure.
<9> A resin composition containing the multifunctional vinylbenzyl compound according to any one of <1> to <8>.
<10> The resin composition according to <9>, wherein a cured product of the resin composition has a residual mass ratio following heating, represented by the mass following heating at 800° C. relative to the mass prior to heating, that is at least 25% by mass.
<11> The resin composition according to <9> or <10>, wherein a cured product of the resin composition has a dielectric loss tangent at a measurement temperature of 25° C. and a frequency of 10 GHz that is within a range from 0.0001 to 0.0020.
<12> A prepreg formed using a resin composition containing the multifunctional vinylbenzyl compound according to any one of <1> to <8> and a fibrous substrate.
<13> A metal-clad laminate formed using the prepreg according to <12> and a metal foil.
<14> A resin film formed using a resin composition containing the multifunctional vinylbenzyl compound according to any one of <1> to <8>.
<15> A printed wiring board containing a cured product of a resin composition containing the multifunctional vinylbenzyl compound according to any one of <1> to <8>.
<16> A semiconductor package containing a printed wiring board containing a resin cured product, and a semiconductor element, wherein
   the resin cured product is a cured product of a resin composition containing the multifunctional vinylbenzyl compound according to any one of <1> to <8>.

### EXAMPLES

The present invention is described below in further detail using a series of examples, but the present invention is not limited to the following examples.

### [Method for Measuring Weight Average Molecular Weight (Mw)]

Weight average molecular weight (Mw) values were measured using the following procedure.

Namely, the weight average molecular weight (Mw) was determined using gel permeation chromatography (GPC), from a calibration curve produced using standard polystyrenes. The calibration curve was approximated as a cubic equation using a set of standard polystyrenes: TSK Standard Polystyrenes (Types A-500, A-2500, A-5000, F-2, F-2, F-4, F-40, F-128, F-288) [brand names, manufactured by Tosoh Corporation]. The GPC measurement conditions are shown below.
Apparatus: high-speed GPC device HLC-8320GPC
Detector: ultraviolet absorption detector UV-8320 [Tosoh Corporation]
Columns: guard column: TSKgel guard column Super (HZ)-M+, columns: TSKgel SuperMultipore HZ-M (two columns), reference columns: TSKgel SuperH-RC (two columns), (all product names from Tosoh Corporation)
Column sizes: 4.6×20 mm (guard column), 4.6×150 mm (columns), 6.0×150 mm (reference columns)
Eluent: tetrahydrofuran
Sample concentration: 10 mg/mL
Injection volume: 2 μL
Flow rate: 0.35 mL/minute
Measurement temperature: 40° C.

### [Preparation of Multifunctional Vinylbenzyl Compounds]

### Production Examples 1 to 4

Formulations of the multifunctional vinylbenzyl compounds are shown in Table 1. The blend amounts shown in the table represent parts by mass.

A reaction vessel of capacity 500 mL fitted with a stirring device, a thermometer, a reflux tube and a nitrogen inlet was charged with indene, 4,4′-bis(chloromethyl)biphenyl, chloromethylstyrene, a phase transfer catalyst, a polymerization inhibitor, pure water, and toluene as a solvent, using the respective amounts shown in the table, and the mixture was stirred under heat at 40° C. while nitrogen was blown into the vessel at a flow rate of 50 ml/minute.

Subsequently, an aqueous solution of sodium hydroxide (NaOH) with a concentration of 48% by mass (manufactured by Kanto Chemical Co., Inc.) was added dropwise over a period of 20 minutes as a basic compound in the amount shown in Table 1, and stirring was then continued for a further 9 hours at 60° C. The nitrogen flow was continued throughout the reaction. The temperature was then cooled to room temperature (25° C.), and following neutralization with a 10% aqueous solution of hydrochloric acid, the product was washed three times with pure water, and the organic phase was then precipitated in methanol, yielding the multifunctional vinylbenzyl compounds 1 to 4.

The chloromethylstyrene used was a product [CMS-P] manufactured by AGC Seimi Chemical Co., Ltd., (a mixture of the m-isomer and the p-isomer with an m-isomer content of about 50% by mass and a p-isomer content of about 50% by mass).

Tetra-n-butylammonium bromide (manufactured by Kanto Chemical Co., Inc.) was used for the phase transfer catalyst.

Phenothiazine was used for the polymerization inhibitor.

The weight average molecular weights (Mw) of the multifunctional vinylbenzyl compounds 1 to 4 are shown in Table 1.

TABLE 1
Formulations and Weight average molecular weights
(Mw) of Multifunctional vinylbenzyl compounds

| Production Example Number | 1 | 2 | 3 | 4 |
|---|---|---|---|---|
| Multifunctional vinylbenzyl | 1 | 2 | 3 | 4 |
| compound number | | | | |
| Indene | 44.7 | 34.6 | 37.8 | 36.2 |
| 4,4′-bis(chloromethyl)biphenyl | 40.5 | 45.8 | 41.7 | 32.0 |
| Chloromethylstyrene | 54.4 | 46.4 | 60.9 | 68.0 |
| Phase transfer catalyst | 9.0 | 7.7 | 8.4 | 8.0 |
| Pure water | 1.8 | 1.8 | 1.8 | 1.8 |
| Polymerization inhibitor | 0.2 | 0.2 | 0.2 | 0.2 |
| Toluene | 99.2 | 134.6 | 99.4 | 96.3 |
| NaOH aqueous solution | 107.1 | 100.6 | 110.0 | 105.3 |
| (concentration: 48% by mass) | | | | |
| Weight average molecular | 1,000 | 1,900 | 1,200 | 800 |
| weight (Mw) | | | | |

### Examples 1 to 4

Each of the multifunctional vinylbenzyl compounds 1 to 4 obtained in the production examples was dissolved in toluene, thus obtaining resin compositions of Examples 1 to 4, each having a solid fraction concentration of about 60% by mass.

### Comparative Examples 1 to 3

In Comparative Examples 1 to 3, the compounds 1 to 3 listed below were each dissolved in toluene, thus obtaining resin compositions of Comparative Examples 1 to 3, each having a solid fraction concentration of about 60% by mass.
Compound 1:1-ethenyl-4-[2-(4-ethenylphenyl)ethyl]benzene (manufactured by Ningbo Inno PharmChem Co., Ltd.)
Compound 2: a xylylene-type vinylbenzyl-modified resin (product name: STR-2000, manufactured by Nippon Kayaku Co., Ltd.)
Compound 3: a vinylbenzyl-modified resin of an oligo-phenylene-ether (product name: OPE-2St, manufactured by Mitsubishi Gas Chemical Co., Inc.)

The structural formulas of these compounds 1 to 3 are shown below.

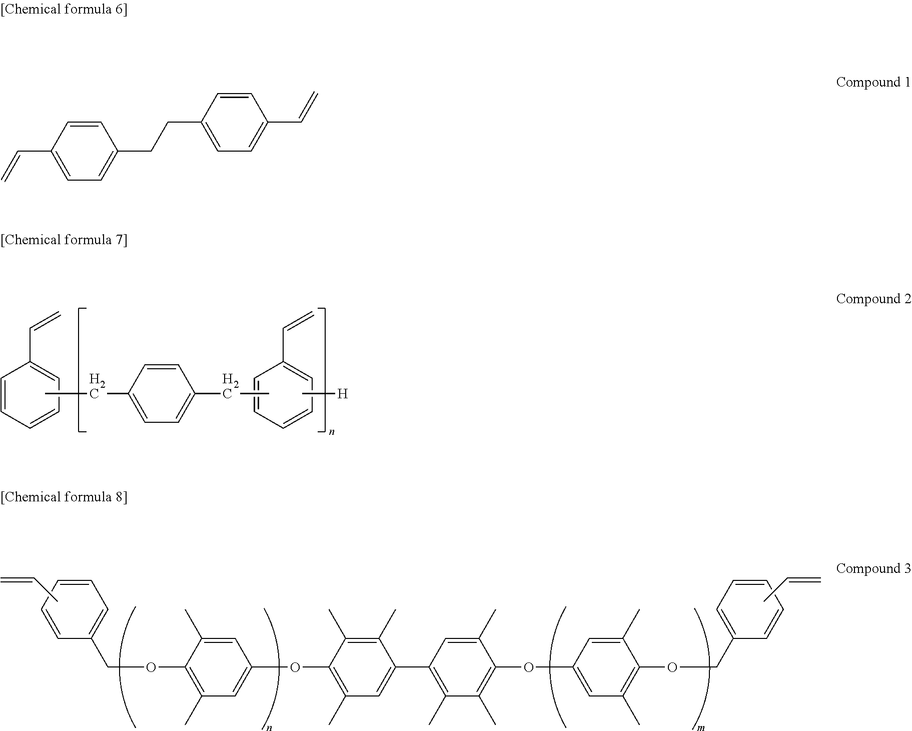

### [Preparation of Resin Sheets]

Each of the resin compositions obtained in the above examples was applied to a polyethylene terephthalate (PET) film of thickness 38 μm (product name: G2000, manufactured by Teijin Ltd.), and then dried under heating at 110° C. for 5 minutes to prepare a resin film in a B-stage state. This resin film was separated from the PET film, and then ground to form a resin powder. The compound 1 is in powder form, and therefore was simply used without further modification as the resin powder, without requiring any drying under heat or grinding.

Subsequently, the resin powder was placed in a Teflon (a registered trademark) sheet having a die shape of thickness 1 mm×length 50 mm×width 30 mm formed therein, and a low-profile coper foil of thickness 18 μm (product name: SI-VSP, manufactured by Mitsui Mining & Smelting Co., Ltd.) was arranged on both sides of the resin powder with the S-surface (gloss surface) of the copper foil contacting the resin powder. Vacuum heated compression molding was then conducted under conditions including a temperature of 150° C., a pressure of 1.5 to 2.0 MPa, and a molding time of 120 minutes, and additional heated molding was then conducted at a temperature of 180° C. for 300 minutes to cure the resin composition. Subsequently, the copper foil was removed from both surfaces, yielding a resin sheet (thickness of resin sheet: 1 mm).

### [Evaluation Methods]

The evaluations described below were conducted using the resin sheets obtained above. The results are shown in Table 2.

### (Dielectric Loss Tangent (Df))

A test piece was prepared by cutting each of the resin sheets obtained above to a size of 1 mm×50 mm. The dielectric loss tangent (Df) of the test piece at an atmospheric temperature of 25° C. in the 10 GHz band was then measured in accordance with the Split Post Dielectric Resonator method.

Measurement apparatus: PNA Network Analyzer N5222B, manufactured by Agilent Technologies, Inc.

### (Residual Mass Ratio Following Heating)

Each of the resin sheets obtained above was cut to form a test piece. Using a TG/DTA apparatus, this test piece was heated to 800° C. under conditions including a stream of nitrogen (100 ml·min⁻¹) and a rate of temperature increase of 10° C.·min⁻¹. The residual mass ratio following heating (% by mass) was determined from the ratio of the mass of the test piece following heating relative to the mass of the test piece prior to heating.

Measurement apparatus: TG/DTA7300, manufactured by Hitachi High-Tech Science Corporation

TABLE 2
Evaluation Results

| | Examples | | | | Comparative Examples | | |
|---|---|---|---|---|---|---|---|
| | 1 | 2 | 3 | 4 | 1 | 2 | 3 |
| Dielectric loss tangent (Df) | 0.0019 | 0.0017 | 0.0016 | 0.0014 | 0.0023 | 0.0021 | 0.0029 |
| Residual mass ratio following | 28.7 | 31.4 | 29.0 | 28.7 | 19.3 | 21.2 | 19.9 |
| heating (% by mass) | | | | | | | |

As shown in the table, it is evident that Examples 1 to 4 all had large residual mass ratios following heating and therefore exhibited superior flame retardancy, and had low dielectric loss tangent (Df) values, indicating excellent dielectric characteristics.

This application is related to the subject matter disclosed in prior Japanese Application 2023-074727 filed on Apr. 28, 2023, the entire content of which is incorporated herein by reference. It should be noted that, besides the embodiments already described above, various modifications and variations can be made in these embodiments without departing from the novel and advantageous features of the present invention. Accordingly, it is intended that all such modifications and variations are included within the scope of the appended claims.

1. A multifunctional vinylbenzyl compound obtained by a reaction between a compound having an aromatic condensed ring, a compound having a biphenylene group, and a compound having a vinylbenzyl group.

2. The multifunctional vinylbenzyl compound according to claim 1, wherein the compound having an aromatic condensed ring includes indene.

3. The multifunctional vinylbenzyl compound according to claim 1, wherein the compound having a biphenylene group includes a 4,4′-bis(haloalkyl)biphenyl.

4. The multifunctional vinylbenzyl compound according to claim 1, wherein the compound having a vinylbenzyl group includes a vinylbenzyl halide.

5. A multifunctional vinylbenzyl compound containing a unit having an aromatic condensed ring and a unit having a biphenylene group, wherein
the multifunctional vinylbenzyl compound has a structure in which the aromatic condensed rings are respectively bonded, either directly or via a linking group, to two carbon atoms on rings of the biphenylene group, with the linking group being a divalent hydrocarbon group, and
also has a vinylbenzyl group bonded directly to a carbon atom on a ring of the aromatic condensed ring.

6. The multifunctional vinylbenzyl compound according to claim 5, wherein
the unit having an aromatic condensed ring has an indene ring, and
has the vinylbenzyl group bonded directly to at least one of carbon atoms at position 1, position 2 and position 3 of the indene ring.

7. A multifunctional vinylbenzyl compound represented by formula (1) shown below: 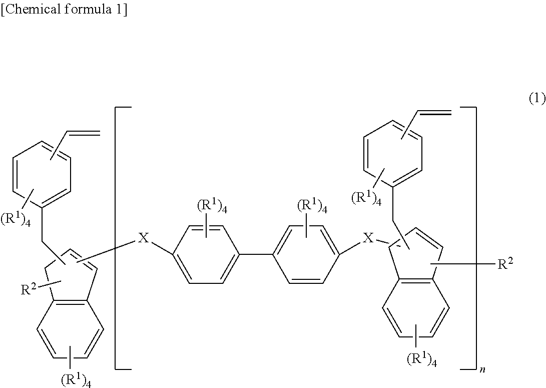
wherein in formula (1):
each R¹ independently represents a monovalent group of 1 to 30 carbon atoms or a hydrogen atom,
each R² independently represents a monovalent group of 1 to 30 carbon atoms, a hydrogen atom, or a bonding location with another structure,
each X independently represents an alkylene group of 1 to 4 carbon atoms or a single bond, and
n is an integer of 1 or greater.

8. The multifunctional vinylbenzyl compound according to claim 7, containing a partial structure represented by formula (2) shown below: 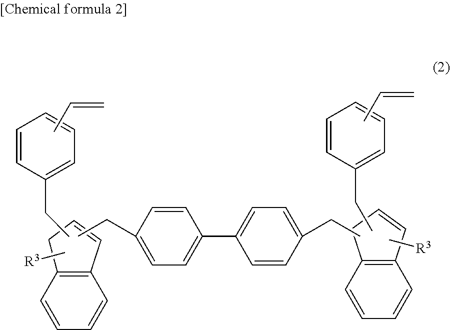
wherein in formula (2), each R³ independently represents a monovalent group of 1 to 30 carbon atoms, a hydrogen atom, or a bonding location with another structure.

9. A resin composition comprising the multifunctional vinylbenzyl compound according to claim 1.

10. The resin composition according to claim 9, wherein a cured product of the resin composition has a residual mass ratio following heating, represented by a mass following heating at 800° C. relative to a mass prior to heating, that is at least 25% by mass.

11. The resin composition according to claim 9 wherein a cured product of the resin composition has a dielectric loss tangent at a measurement temperature of 25° C. and a frequency of 10 GHz that is within a range from 0.0001 to 0.0020.

12. A prepreg formed using a resin composition comprising the multifunctional vinylbenzyl compound according to claim 1 and a fibrous substrate.

13. A metal-clad laminate formed using the prepreg according to claim 12 and a metal foil.

14. A resin film formed using a resin composition comprising the multifunctional vinylbenzyl compound according to claim 1.

15. A printed wiring board containing a cured product of a resin composition comprising the multifunctional vinylbenzyl compound according to claim 1.

16. A semiconductor package containing a printed wiring board containing a resin cured product, and a semiconductor element, wherein
the resin cured product is a cured product of a resin composition comprising the multifunctional vinylbenzyl compound according to claim 1.

17. A resin composition comprising the multifunctional vinylbenzyl compound according to claim 5.

18. A resin composition comprising the multifunctional vinylbenzyl compound according to claim 7.
